(19) United States
(12) Patent Application Publication
(10) Pub. No.: US 2026/0044423 A1
(43) Pub. Date: Feb. 12, 2026

(54) APPARATUS INCLUDING STACK TESTING MECHANISM AND ASSOCIATED METHODS

(71) Applicant: Micron Technology, Inc., Boise, ID (US)

(72) Inventors: Bokuba Nwengela, El Dorado Hills, CA (US); Raymond Chang, Sacramento, CA (US); Raghukiran Sreeramaneni, Frisco, TX (US); Nevil N. Gajera, Meridian, ID (US)

(21) Appl. No.: 19/287,461

(22) Filed: Jul. 31, 2025

Related U.S. Application Data
(60) Provisional application No. 63/680,318, filed on Aug. 7, 2024.

(51) Int. Cl. G06F 11/27; G06F 11/273

(52) U.S. Cl. CPC G06F 11/27; G06F 11/273

(57) ABSTRACT

An apparatus including a stack testing mechanism and associated systems and methods are disclosed herein. The stack testing mechanism may be configured to test individual dies after they are stacked together. The stack testing mechanism may include circuits to separately identify and access individual dies, and based on the individual access, utilize self-test circuits within each die to test functionality of the corresponding die.

### CROSS-REFERENCE TO RELATED APPLICATION(S)

The present application claims priority to U.S. Provisional Ser. No. 63/680,318, filed Aug. 7, 2024, the disclosure of which is incorporated herein by reference in its entirety.

### TECHNICAL FIELD

The present technology is directed to apparatuses, such as semiconductor devices including memory and processors, and several embodiments are directed to semiconductor devices that include stack testing mechanisms.

### BACKGROUND

An apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, reducing power consumption, or reducing manufacturing costs, among other metrics. However, attempts to meet the market demands, such as by reducing the overall device footprint and increasing circuit density within a given physical area/space, can often introduce challenges in other aspects, such as for maintaining circuit robustness and/or failure detectability.

### BRIEF DESCRIPTION OF THE DRAWINGS

FIG. 1 is a cross-sectional view of a system-in-package device in accordance with embodiments of the technology.

FIG. 2 is a block diagram of a memory device in accordance with embodiments of the technology.

FIG. 3 is a block diagram of example die-level testing circuits.

FIG. 4 is a block diagram of a first example stack testing mechanism in accordance with embodiments of the technology.

FIG. 5 is a block diagram of a second example stack testing mechanism in accordance with embodiments of the technology.

FIG. 6A-FIG. 6C illustrate a self-identification sequence of dies within a die stack in accordance with embodiments of the technology.

FIG. 7A and FIG. 7B are flow diagrams illustrating example methods of operating an apparatus in accordance with an embodiment of the present technology.

FIG. 8 is a flow diagram illustrating an example method of manufacturing an apparatus in accordance with an embodiment of the present technology.

FIG. 9 is a block diagram of a system that includes an apparatus configured in accordance with embodiments of the present technology.

### DETAILED DESCRIPTION

As described in greater detail below, the technology disclosed herein relates to an apparatus, such as for memory systems, systems with memory devices, related methods, etc., for facilitating self-test of a die stack. An apparatus (e.g., a memory device, such as an HBM and/or a RAM, and/or a corresponding system) can include a stack testing mechanism included within each die and distributed across the dies within the die stack. The stack testing mechanism can be configured to provide communicative access to/from and further adapt existing die-level self-test circuits after the dies are incorporated into a stack. Accordingly, the stack testing mechanism can facilitate self-testing of individual dies after they are integrated into a singular stack using the existing die-level self-test circuits. Stated differently, the stack testing mechanism can enable testing of individual dies within a stack to check for manufacturing defects introduced during the stack integration process. For example, the stack testing mechanism can enable testing of a stack of memory dies before it is formed into an HBM (e.g., before the memory stack is attached over an interface die).

As a result, the stack testing mechanism can reduce manufacturing costs and improve yields by detecting manufacturing defects (e.g., defects caused by the stack formation) earlier in the overall manufacturing process, such as before a memory stack is integrated over an interposer and an overarching system-in-package (SiP). The stack testing mechanism can further enable fixes to reverse the defect or replace the affected die, thereby further improving the stack yield.

In some embodiments, the stack testing mechanism can include, at individual dies (e.g., semiconductor dies), a vertical Through Silicon Via (TSV) coupled to each die-level test interface (e.g., test pad) that are coupled to the die-level test circuits. Accordingly, when stacked together, the die-level test interfaces of the stacked dies can be coupled together, and the coupled test interfaces can be used to communicate signals to/from multiple dies within the stack and devices external to the stack (e.g., a testing apparatus).

Further, the stack testing mechanism can include, at the individual dies, a die identifier circuit (e.g., buffer or counter) that can be dynamically configured to store a unique identifier for the corresponding die within the stack. The stack testing mechanism can be configured to communicate with an external tester to generate and locally store unique identifiers at each of the dies within the stack. In some embodiments, the external system (e.g., a testing controller) can communicate with a targeted die using the corresponding identifier communicated over the test interface bus. For example, each command can be communicated with the unique identifier for the targeted die, and the targeted die can respond to the received command when the accompanied identifier matches the identifier value stored locally within the identifier circuit. In other embodiments, the stack testing mechanism can include, at the individual dies, a separate identifier interface configured to receive the identifier for the die targeted by the incoming commands or the identifier of the die providing the outgoing data. Details regarding the stack testing mechanism are described below.

### Example Environment

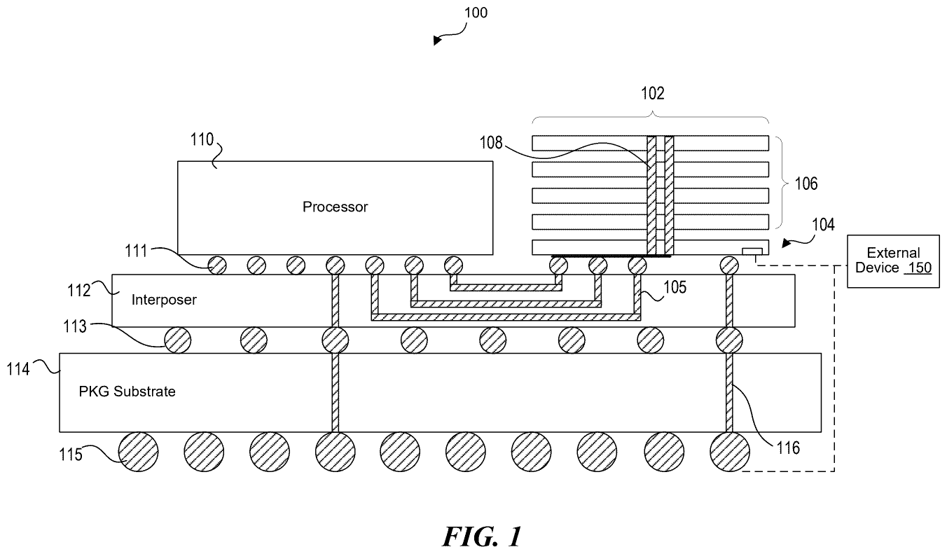

FIG. 1 illustrates a schematic cross-sectional view of a SiP device 100 (i.e., an example apparatus) in accordance with embodiments of the technology. The SiP 100 can include the memory device 102 and the processor 110, which are packaged together on a package substrate 114 along with an interposer 112. The processor 110 may act as a host device of the SiP 100.

In some embodiments, the memory device 102 may be an HBM device that includes an interface die (or logic die) 104 and one or more memory core dies 106 stacked on the interface die 104. The memory device 102 can include one or more through silicon vias (TSVs) 108, which may be used to couple the interface die 104 and the core dies 106.

The interposer 112 can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. Although only three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate may further include direct access (DA) bumps coupled through the package substrate 114 and interposer 112 to the interface die 104.

In some embodiments, the direct access bumps 116 (e.g., one or more of the bumps 115) and/or other bumps may be organized into a probe pad (e.g., a set of test connectors). An external device 150, such as a tester, may be coupled onto the probe pad in order to directly communicate with the memory device 102. In other words, the external device 150 may send signals to and/or receive signals from the memory device 102 without the signals passing through the processor 110 after the memory device 102 is mounted on the interposer 112. The external device 150 may be used to test the memory device 102 before it is mounted on the interposer 112 and/or coupled to the processor 110.

The external tester can function as a host device for the test that interacts with a built-in self-test (BIST) circuit of the memory device 102 to implement the test. The tester may be used to load one or more test patterns into a test pattern memory (e.g., predetermined registers) of the interface die 104. The tester may then provide one or more test instructions along the direct access terminals 116. The interface die 104 may perform one or more tests on the memory device 102 based on the test instructions and the loaded test patterns and may generate result information. The test results can be monitored during the test to find when failure occurs or read at the end of the test for a pass/fail conclusion.

The test patterns and the instructions can correspond to one or more tests performed on the memory device 102. The test may involve loading a pattern of data into one or more memory cells of the memory device 102 as part of a write operation, retrieving the stored information from the memory cells as part of a read operation, and comparing the written data to the read data. A test may be performed using the BIST circuit of the memory device 102. The tests may be performed using extremely long test patterns with random characteristics, which may require more storage space than is practical in the BIST circuit. Such tests may be performed by directly sending test patterns and instructions through the DA terminals 116.

### Example Subsystem-Level Test Circuit

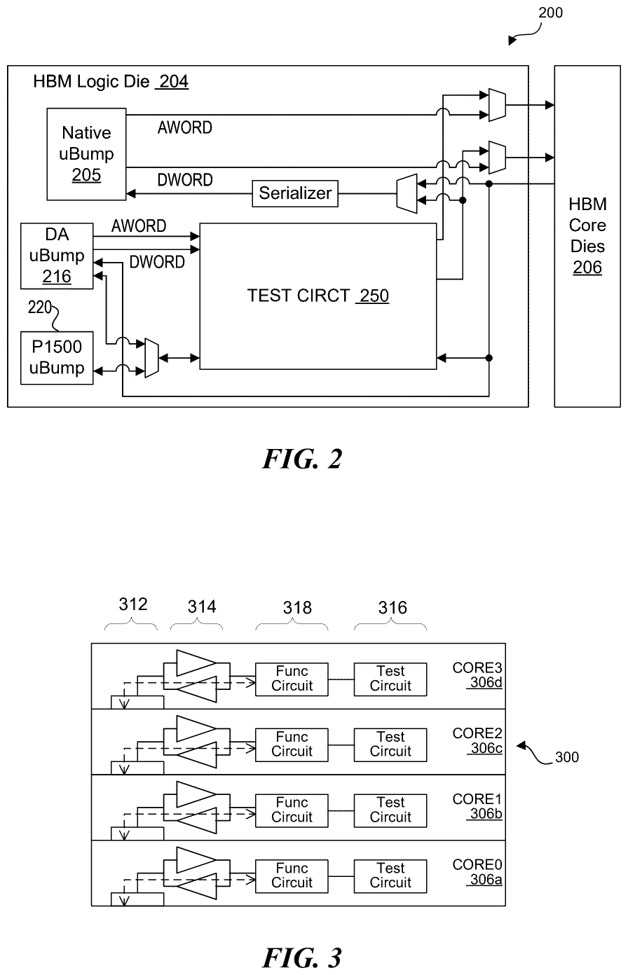

FIG. 2 is a block diagram of a memory device 200 (i.e., an example apparatus, such as the memory device 102 of FIG. 1) in accordance with embodiments of the technology. For example, the memory device 200 can include the HBM device. The memory device 200 may include an interface die 204 and one or more core dies 206. In some embodiments, the memory device 200 can include any number of core dies 206 coupled to the interface die 204 (e.g., there may be 2, 4, 8, or other quantities of core dies 206).

The memory device 200 can include different interface terminals for accessing the core die(s) 206 and/or one or more circuits of the memory. In some embodiments, the different interface terminals can include native micro-bumps (uBumps) 205, DA uBumps 216, and/or test interface uBumps 220. The test interface uBumps 220 may be part of a specific interface protocol, such as the IEEE 1500 interface (also referred to as a P1500 interface). The native uBumps 205 may, in some embodiments, be included in the uBumps 111 of FIG. 1. The native uBumps 205 may be coupled to a processor (e.g., the processor 110 of FIG. 1) via one or more connections (e.g., the channels 105 of FIG. 1). The native uBumps 205 and the connections can enable the processor to access information (via, e.g., read or write operations and the corresponding exchange of information) in the core die(s) 206. For example, the core dies 206 may receive a command (e.g., a read command) along with address information (AWORD), such as such as a row address, column address, a bank address, a die identifier, or the like, that specifies a location for the memory access. The AWORD may also include command information, such as clock signals used for the timing of operations and command identifiers. The accessed information (DWORD), such as the write data or the read data can also be exchanged through the native uBumps 205.

In some embodiments, the interface die 204 may include a serializer configured to process the DWORD between the core dies 206 to the native uBumps 205. For example, the serializer may receive information in parallel along a first number of data lines (e.g., from the core 206), and then provide that information in a serial fashion along a second number of data lines (e.g., to the native uBumps 205). The serializer may be used to multiplex a number of outputs (e.g., from the core 206) to a smaller number of data lines (e.g., to the native uBumps 205).

In addition to the operational configurations (e.g., native operational mode) associated with the native uBumps 205, the memory device 200 can be configured to operate in a test mode (e.g., a BIST mode or other self-test modes). In test mode, the memory device 200 can determine one or more characteristics (e.g., signal responses, manufacturing defects, failure or error related aspects, or other aspects of the circuit) of the memory device 200. The memory device 200 may utilize the P1500 uBumps 220 and/or the DA uBumps 216 as the test interface. For example, the P1500 uBumps 220 may be used to communicate signals with the host device according to a predetermined sequence or protocol for sending and receiving signals.

The memory device 200 may use a stack test circuit 250 (e.g., a BIST circuit) to process the signals communicated through the P1500 uBumps 220 and/or the DA uBumps 216. The stack test circuit 250 can be configured to implement the self-test for the memory device 200 (e.g., the overall HBM). The test circuit can include a BIST sequencer coupled to a test interface circuit (e.g., a P1500 circuit) that is configured to interpret signals according to the P1500 protocol. For example, the P1500 circuit may translate signals received at the P1500 uBumps into signals usable by other circuits of the memory device 200 and vice versa.

During a test mode (e.g., a BIST operational mode), instructions may be received (from, e.g., the external device 150 of FIG. 1) to operate the stack test circuit 250 (e.g., the BIST sequencer 228) to perform a test of the memory device 200. The stack test circuit 250 may generate a test sequence (e.g., a string of logical bits) to write to memory cells of the core die 206. The stack test circuit 250 may include a number of registers which may be used to store addresses of memory cells to test as well as a test sequence. In some embodiments, the test sequence and/or addresses may be generated within the stack test circuit 250 based on instructions. For example, the stack test circuit 250 may perform a test on a certain address value, increment that address value by one, and then perform the test again. In some embodiments, the stack test circuit 250 may load the test sequences into a look-up-table, such as data topology (DTOPO) circuit. Each entry in the DTOPO circuit may be associated with a pointer value (e.g., an index value) and in a manner similar to the addresses the stack test circuit 250 may generate a sequence of pointer values.

During a write portion of a test, the stack test circuit 250 may provide address information (e.g., one or more row and column addresses) and a test sequence (e.g., data to be written to the memory cells specified by the address information) to a logic-die input buffer (e.g., a register, such as a write FIFO (WFIFO)). In some embodiments, the stack test circuit 250 may provide the address information to the logic-die input buffer, and may provide index information to the DTOPO circuit, which may provide the test sequence to the logic-die input buffer. Based on the address information provided from the WFIFO, the test sequence may be written to the memory cells specified by the address information.

During a read portion of a test, the stack test circuit 250 may provide address information to retrieve a test sequence previously stored in the core die 206. Information may be read out from the memory cells specified by the address information to a logic-die output buffer (e.g., a read FIFO (RFIFO)). The logic-die output buffer circuit may generally be similar to the logic-die input buffer, except that the output buffer may receive information from the core die 206 and then provides it on to other circuits of the interface die 204.

The interface die 204 may include an error catch memory (ECM) circuit configured to generate error related results based on the read test sequence. The ECM circuit may be coupled to the address information and test sequences provided to the input buffer, and include one or more registers (e.g., BIST registers and/or MISR output registers) used to store the written test sequences as well as address information. When a read operation is performed, the ECM circuit may compare the read test sequence from the output buffer to the test sequence which was written to those memory cells as part of an earlier write operation. The ECM circuit may generate the results (e.g., indication of mismatches, failed memory cells, or the like) based on such comparison. The ECM circuit may then provide the result information to the P1500 circuit, which may then provide the result information out of the memory over the P1500 uBumps 220 and/or the DA uBumps 216.

In addition to or as an alternative to the P1500 uBump 220, the memory device 200 can provide access to the core dies 206 through the DA ubump 216 (e.g., the DA bumps 116 of FIG. 1). The memory device 200 can be configured to provide direct accesses thereto, such as by bypassing other components of a SiP (e.g., such as the processor 110) through the DA bump 216. These DA uBumps 216 may, in some embodiments, be organized into a probe pad, where an external device (e.g., the external device 150) may be coupled to DA uBumps 216 in order to access the interface die 204 (and through it the core die 206). For example, the memory device 200 can communicate directly with an external tester through the DA uBumps 216 to implement a test. The signals may be communicated according to the P1500 interface protocol. Accordingly, the DA uBumps 216 may be used to implement the self-test described above for the P1500 uBump 220, such as by load information to/from test circuits (e.g., the DTOPO circuit 230 and/or the ECM circuit 232) through the DA uBumps 216. The test information may be communicated between the DA uBumps 216 and the P1500 circuit 224 and then communicated to/from the other circuits as described above.

### Die-Level Test Circuit

In addition to the stack test circuit 250, individual core dies can include local self-test circuits. The different test circuits can effectively correspond to self-testing of circuits at different levels of integration or at different times during manufacturing. For example, the die-level self-test circuits can be used to self-test and validate the individual memory dies (e.g., the individual core dies 206, such as DRAM dies). The stack test circuit 250 can be used to test the memory device 200 after the validated core dies 206 are stacked together and then over/onto the logic die 204.

For illustrative purposes, FIG. 3 is a block diagram of example die-level testing circuits. FIG. 3 shows an example stack 300 of dies 306 (e.g., core memory dies 306a-306d for an example die stack). Conventionally, each die can have a local (self) test circuit configured to test/validate a functional circuit within the die.

As shown in FIG. 3, each of the dies 306 can include an external interface 312, such as a port, a communication/contact pad, a connector, or the like, configured to communicate with a circuit external to the corresponding die. The external interface 312 can be used to physically receive signals (e.g., commands, data, or the like associated with the self-test) from an external die-tester device and/or send signals (e.g., test results) to the external die-tester device.

Each of the dies 306 can further include a communication circuit 314, such as a receiver and/or a transmitter (e.g., a transceiver), coupled to the external interface 312. The communication circuit 314 can be configured to internally receive and store incoming signals and/or generate and drive output signals.

The communication circuit 314 can be coupled to a die-level test circuit 316, which can be configured to test and assess functionalities of the die's functional circuitry 318. For example, for memory dies (e.g., DRAM), the functional circuitry 318 can include storage circuits (e.g., capacitors) and corresponding support circuits used to identify specific locations within the storage circuits and read/write to the identified locations of the storage circuits. The die-level test circuit 316 can be similar to the test circuit 250 of FIG. 2 but for a die-level test instead of a subsystem/HBM level test. For example, the die-level test circuit 316 can be configured to (1) store/write predetermined data (e.g., character strings or other known values) at one or more locations within the local storage circuit, (2) read data stored at the one or more locations within the local storage circuit, and (3) compare the read data to the predetermined data. Based on the comparison, the die-level test circuit 316 and/or the corresponding external tester can assess the functionality of the tested storage locations. The test self-test results can indicate failures or defects within the tested die, and the results can be used to implement internal remedial actions (e.g., replacement of defective cells with additional/backup cells). Otherwise, the die can be scrapped when the test results indicate predetermined mode/pattern and/or amount of failures or defects.

The die-level test circuit 316 can test the corresponding functional circuit during and/or after manufacturing of the die. For example, a manufacturer may implement a self-test or a portion thereof during wafer-level manufacturing processes and/or after completing manufacturing of the die (e.g., after singulating the dies from the wafer). As such, conventional die-level test circuits are not directly accessible after the tested/validated dies are attached or stacked on other structures. As shown in FIG. 3, when dies 306b-d are stacked over die 306a, the die external interfaces 312 (e.g., test pads) on the stacked dies 306b-d are covered and inaccessible. As a result, the die-level test circuits 316 for dies 306b-d can no longer be used to self-test the corresponding dies after the stacking process. Thus, testing the functionality of the stack 300 and/or the dies 306b-d can require an additional step/structure, such as the interface die 104 of FIG. 1 and/or the interposer 112 of FIG. 1 for the memory device 102 of FIG. 1 (e.g., HBM).

### Stack-Level Test Circuits

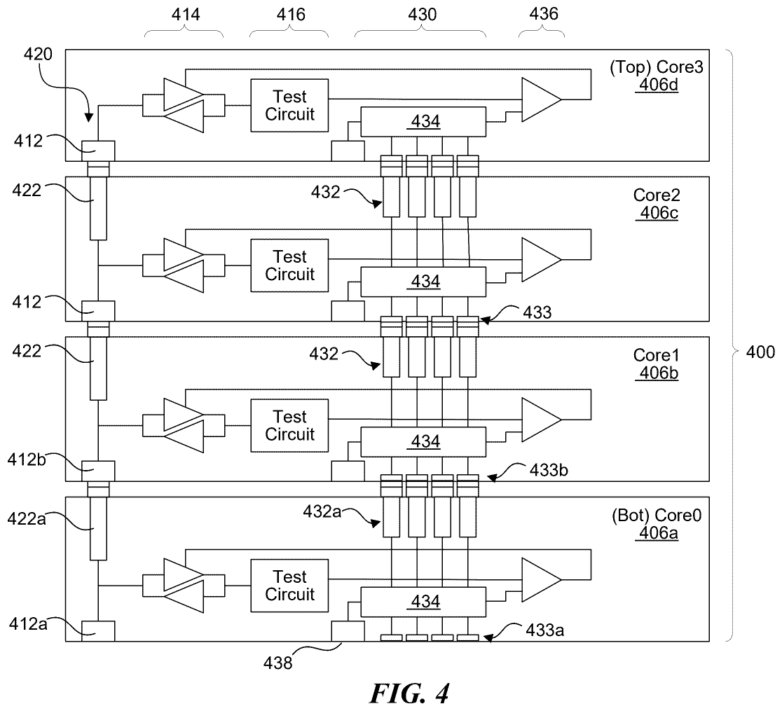

Embodiments of the technology described herein can include a stack testing mechanism that is at least partially included within each die and interacts with components in other dies to utilize the die-level test circuits in a stack-testing scenario. FIG. 4 is a block diagram of a first example stack testing mechanism in accordance with embodiments of the technology. A die stack 400 can include multiple dies 406, such as for dies 406b-406d stacked on a bottom or a core die 406a. Similar to the dies 306 of FIG. 3, the dies 406 can each include a die external interface 412 (e.g., a test pad), a die communication circuit 414, and a die-level test circuit 416 that can be leveraged to test local functional circuitry (not shown in FIG. 4).

The stack testing mechanism can include circuitry to configured to self-test the die stack 400 and/or the dies 406b-406d after the dies are stacked to form the die stack 400. In facilitating the stack-level testing, the stack testing mechanism can be configured to leverage the die-level test circuit 416 within each of the dies 406. For example, the stack testing mechanism can include components within each die that can be coordinated to (1) communicate test signals (e.g., commands and/or results) to and from each of the dies, (2) uniquely identify each of the dies within the stack, and (3) uniquely access each of the dies.

For the communications, the stack testing mechanism can include an external communication bus 420 within the die stack 400. The external communication bus 420 can include a communicative path/connection that allows connections and communicative access to the die external interfaces 412 on each of the dies 406 within the stack 400. In some embodiments, the external communication bus 420 can include an external interface via 422 (e.g., TSV) extending vertically and through a body of the corresponding core. Each external interface via 422 can be electrically coupled to (1) the die external interface 412 local to the corresponding die and (2) the die external interface 412 on the die stacked over the local die. For example, an external interface via 422a on a bottom die 406a can be electrically coupled to (1) a local test pad 412a local to the bottom die 406a and (2) an external test pad 412b (e.g., using inter-die connectors, such as direct bonding, posts/pillars, solder, and/or the like) within or on a core die 406b stacked over and directly on the bottom die 406a. Accordingly, the set of external interface vias 422 within the stacked dies 406 can form the external communication bus 420. For the example illustrated in FIG. 4, an external test device can send and receive signals to and from each of the dies 406a-406d through the local test pad 412a on the bottom die 406a. The communicated signals can be effectively broadcasted over the external communication bus 420.

For identifying the individual dies within the stack, the stack testing mechanism can have a self-identifier bus 430 that includes self-identifier vias 432 and self-identifier interfaces 433. The self-identifier bus 430 can include a communicative path/connection that allows connections and communications of self-identification signals to and from each of the dies 406 within the stack 400. Similar to the external communication bus 420, the self-identifier vias 432 (e.g., TSVs) can extend vertically and through a body of the corresponding core. Each of the self-identifier vias 432 on a corresponding die can be electrically coupled to (1) a corresponding one of the self-identifier interfaces 433 (e.g., a corresponding pad) local to the same die and (2) a corresponding one of the self-identifier interfaces 433 local to the stacked die. For example, the self-identifier vias 432a on the bottom die 406a can be electrically coupled to (1) self-identifier interfaces 433a local to the bottom die 406a and (2) self-identifier interfaces 433b (e.g., using inter-die connectors) within or on the core die 406b stacked over and directly on the bottom die 406a.

The self-determined identifier can be utilized during the stack-level self-test using a die identifier circuit 434 configured to generate and/or maintain a unique identifier for the corresponding die. The die identifier circuit 434 can be coupled to the self-identifier vias 432 and the self-identifier interfaces 433 within each die. In some embodiments, the die identifier circuit 434 can include a buffer, a counter, a logic, or a combination thereof. The die identifier circuit 434 can be configured to communicate with the external test device through the self-identifier bus 430 and generate and/or maintain (by, e.g., locally determining and storing) a unique identifier for the corresponding die. Details regarding the die identifier circuit 434 and the self-identification process are described further below.

The stack testing mechanism can further include an access control circuit 436 coupled to the die identifier circuit 434 within each die. The access control circuit 436 (e.g., logic, such as an AND device) can be configured to determine whether the corresponding die is the target of the communication or the current portion of the test. Stated differently, the access control circuit 436 can determine whether the corresponding die is the intended recipient of the communication. In some embodiments, the access control circuit 436 can be coupled to the die identifier circuit 434 and the die eternal interface 412. Accordingly, the access control circuit 436 can compare the die identifier communicated or called out by the external test device to the locally stored identifier value. When the compared values match, the access control circuit 436 can enable the corresponding die to process the received communication. For the illustrated example, the access control circuit 436 can include an AND device that enables the die communication circuit 414 to receive and pass the communication through to the local test circuit 416 when the compared values match.

For illustrative purposes, the access control circuit 436 is shown located downstream from the test circuit 416. Accordingly, the initial communication can be allowed to pass through the test circuit 416 and evaluated at the access control circuit 436. However, it is understood that the access control circuit 436 can be located differently, such as at a more upstream location like at the die external interface 412 or the die communication circuit 414 or between the two. Accordingly, the access control circuit 436 can evaluate the commands and identifier incoming through the external communication bus 420.

As described in further detail below, the stack 400 can interact with an external tester to self-identify the die locations and then, using the identified locations, leverage the local test circuits 416 to test each of the dies 406 within the stack 400. In self-identifying the die locations, the stack 400 and the external device can use a referencing mechanism to identify a die that corresponds to the predetermined reference location within the stack 400. The referencing mechanism, such as a reference interface 438, can be configured to identify that the corresponding die is at a reference position (e.g., a bottom position or a top position) of the die stack 400. Some examples of the referencing mechanism can include a switch, a breakable connection, a resister setting, and/or other similar user-configurable component. For the illustrated example, the reference interface 438 can include a pad that can be connected to a known electrical potential (e.g., electrical ground) or a known load.

In some embodiments, the top and/or bottom dies can be different from other dies in the stack 400. In other embodiment, the dies 406 in the stack 400 can be identical. Further, for illustrative purposes, FIG. 4 shows the vias has having a width and extending downward to illustrate the vertical orientation of the vias. Also, FIG. 4 shows circuit components, such as the die communication circuit 414, the die-level test circuit 416, and/or the self-identifier circuit 436, that may be arranged laterally across one or more planes as a two-dimensional projection across a body of the core.

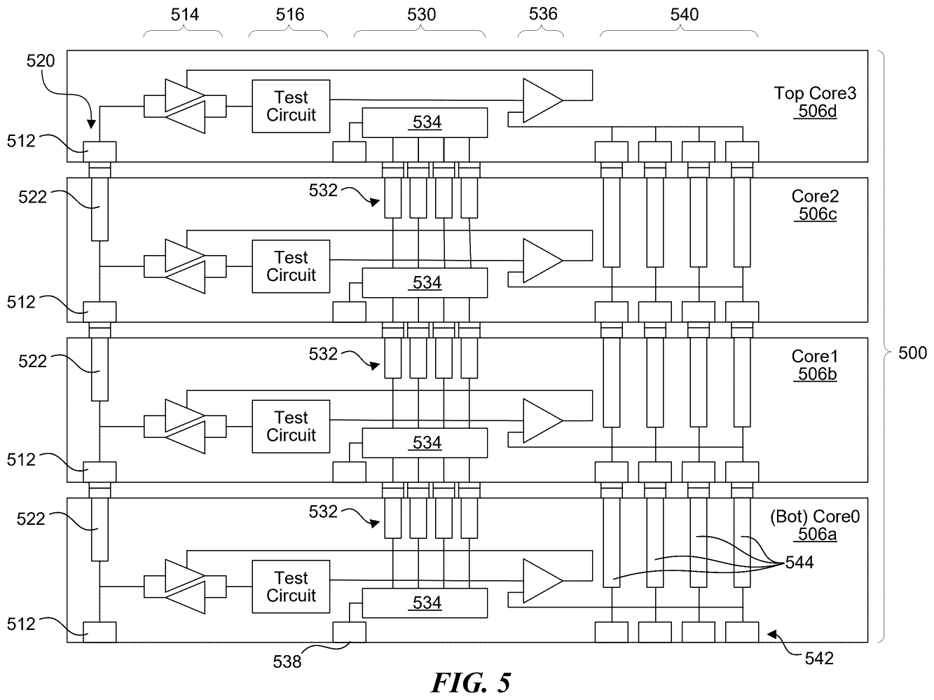

Illustrating a further example, FIG. 5 is a block diagram of a second example stack testing mechanism in accordance with embodiments of the technology. In contrast to the first example that communicates the die selection through the external communication bus 420 of FIG. 2, the second example can be for communicating the die selection through a different path during the stack-level self-test.

For the second example, a die stack 500 can include multiple dies 506, such as for dies 506b-506d stacked on a bottom or a core die 506a. The dies 506 can include components similar to the dies 406 of FIG. 4. For example, the dies 506 can each include a die external interface 512 (e.g., a test pad) a die communication circuit 514, a die-level test circuit 516, a die-level functional circuit (not shown in FIG. 5), an external communication bus 520, an external interface via 522, a self-identifier bus 530 with self-identifier vias 532 and self-identifier interfaces 533, a die identifier circuit 534, a die access control circuit 536, and/or a reference interface 538 that are similar to the corresponding components within the dies 406.

In addition to the similar components, the die stack 500 can include a die selector bus 540 having die selector interfaces 542 (e.g., communication/contact pads, ports, etc.) and die selector vias 544. Like the external communication bus 520, the die selector interfaces 542 can provide an external communication interface for communicating die selection signals with the external tester, and the die selector vias 544 can provide communicative paths that extend across or through the body of the dies 506. Accordingly, the die selector vias 544 on one die can electrically couple with the interfaces of another die (e.g., the stacked die contacting and over the corresponding die). In some embodiments, the die selector bus 540 can allow the die selection signals to be broadcasted over the die selector bus 540.

The die selector bus 540 can be communicatively coupled to the access control circuit 536 within each of the dies 506. Accordingly, the access control circuit 536 can receive the selection signals communicated over the die selector bus 540 and determine whether the corresponding die is targeted by the incoming signal. For example, the access control circuit 536 can compare the value communicated on the die selector bus 540 and the identifier locally stored in the die identifier circuit 534. When the compared values match, the access control circuit 536 can enable the communications on the external communication bus 520 to be locally processed, such as by enabling the local die communication circuit 514 to receive and pass on the received communication on the external communication bus 520.

### Die Self-Identification

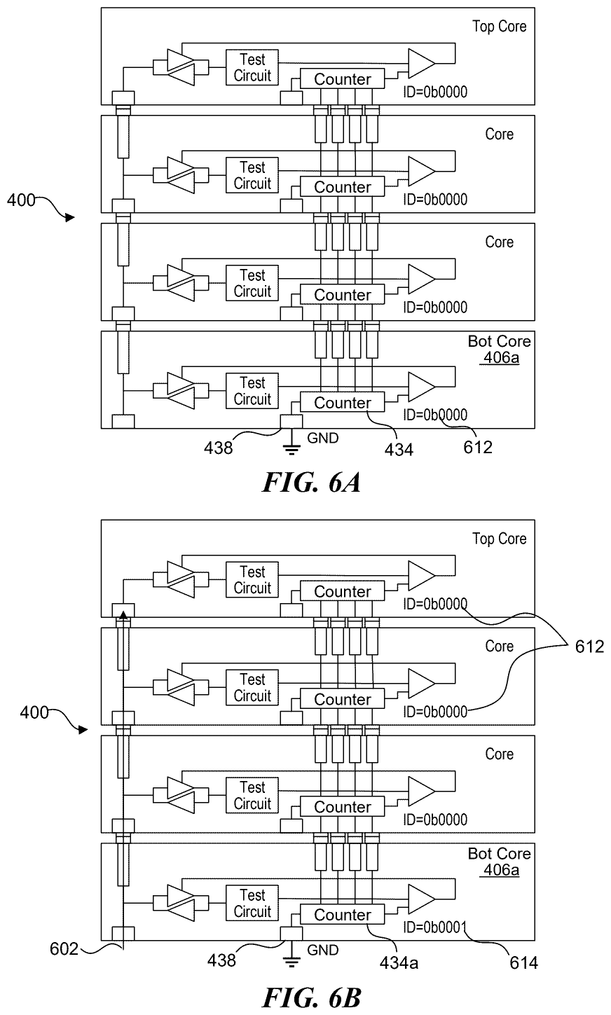

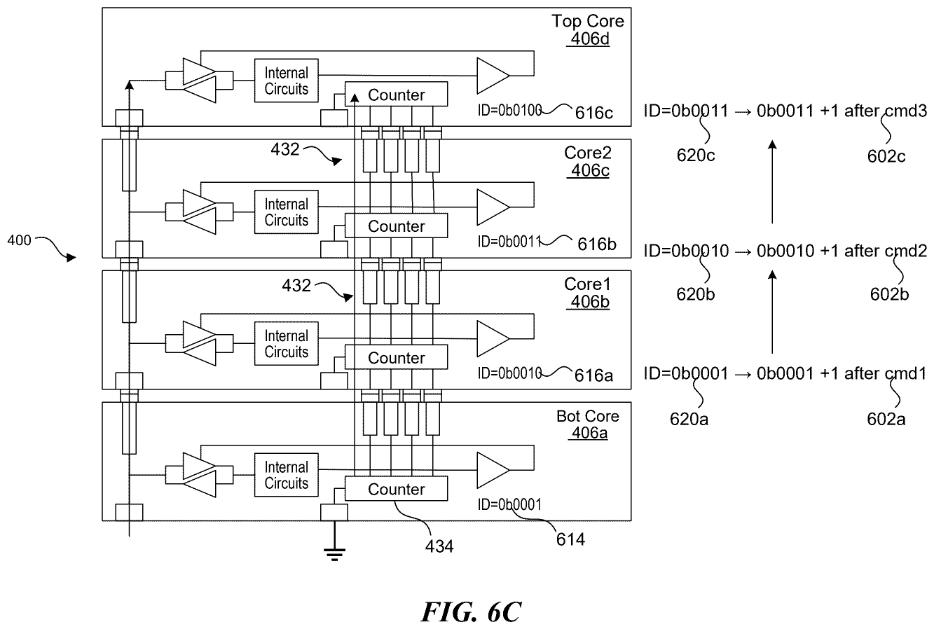

FIG. 6A-FIG. 6C illustrate a self-identification sequence of dies within a die stack in accordance with embodiments of the technology. For illustrative purposes, FIG. 6A-FIG. 6C illustrate the self-identification sequence using the die stack 400. However, it is understood that the stack 500 of FIG. 5 can implement the self-identification sequence described below to identify the dies 506 of FIG. 5 therein. The stack 500 may communicate one or more commands or other signals through the die selector bus 540 of FIG. 5 instead of the external communication bus 520 of FIG. 5 during the self-identification sequence.

FIG. 6A illustrates an initial state of the die stack 400 before initiating the self-identification sequence. The die stack 400 can be initialized for the self-identification, such as by setting a reference position for one of the dies (e.g., a bottom die or a top die). For example, the reference interface 438 of the bottom die 406a can be connected to an electrical ground. Further, each of the die identifier circuits 434 (e.g., a counter) in the die stack 400 can be initialized to and/or have a default identifier value 612 loaded therein. For the illustrated example, the default identifier value 612 can be 0b0000.

FIG. 6B illustrates a first state of the die stack 400 after initiating the self-identification sequence. The external tester and the die stack 400 can communicate with each other according to a predetermined protocol, program, process, or the like. For example, the external tester can issue a command 602 (e.g., a row/column cmd or testmode input) associated with the self-identification. In some embodiments, the dies 406 of FIG. 4 can use internal test logic (e.g., the die-level test circuit 416 of FIG. 1) therein to determine whether the corresponding die has been set as a reference, such as by having the reference interface 438 connected to a known electrical potential (e.g., electrical ground). When the referenced die, such as the bottom die 604a determines the reference setting, a local identifier circuit 434a can update (by, e.g., incrementing up or down) the locally stored value from the default identifier value 612 to a reference identifier value 614. For the illustrated example, the reference identifier value 614 can be 0b0001. In some embodiments, the external tester can verify that the referenced die has accurately self-identified by reading the reference identifier value 614 using a testmode/register readout.

FIG. 6C illustrates a finalized state of the die stack 400 at the end of the self-identification sequence. In reaching the finalized state, the self-identification sequence can include an iterative sequence of issuing commands, localized identification, and/or verification. For example, in some embodiments, the external tester can send a row/column command or a testmode input, and the dies 406 of FIG. 4 can respond by (1) communicating a previous identifier value 620 (e.g., a value within the local die identifier circuit 434 at the time of receiving the command) to the next die in the stack through the self-identifier vias 432 and (2) adjusting (e.g., increment or decrement) the previous identifier value 620 to generate a current identifier value. The current identifier value can be finalized or set as an individual die identifier 616 for the corresponding die and stored within the die identifier circuit 434.

As an illustrative example, the external tester can send a command (e.g., initialization cmd) through the external communication bus 420 of FIG. 4. In response, the bottom die 406a of FIG. 6B can determine the reference connection and set the internal counter to the reference identifier value 614 as described above. After verifying the reference setting, the external tester can send a next command (e.g., cmd0) through the external communication bus 420 for the next iteration. In response, the bottom die 406a can send the reference identifier value 614 to a first stacked die 406b (e.g., core1) through the self-identifier vias 432 on the bottom die 406a. The first stacked die 406b can store the received value (e.g., the reference identifier value 614 from the bottom die 406a) in the die identifier circuit 434 within the first stacked die 406b. The dies 406 can be configured to stop incrementing in response to commands received (1) after detecting the reference setting and/or (2) after communicating the counter value through the local self-identifier vias 432. Accordingly, the bottom die 406a can maintain the self-identifier vias 432 in response to the next command and subsequent commands. The first stacked die 406b can receive and store the received identifier value (e.g., the reference identifier value 614) at the local die identifier circuit 434 within the first stacked die 406b.

Continuing with the illustrative example, the external tester can send a subsequent command 602a (e.g., cmd1) through the external communication bus 420. In response, the bottom die 406a can be configured to not respond based on detecting the reference setting, and the first stacked die 406b (e.g., core1) can adjust, such as by incrementing, the value stored in the local die identifier circuit 434. Accordingly, the locally stored individual die identifier 616a can be adjusted from 0b0001 to 0b0010. Afterwards, the first stacked die 406b can be configured to finalize the stored value based on having received a value through the self-identifier interfaces 433 in the previous iteration and communicate the finalized stored individual die identifier 616a through the local self-identifier vias 432 on the first stacked die 406b. Other dies within the stack 400 can remain non-responsive based on having the initialized conditions, such as the default identifier value 612 within the local die identifier circuit 434 and/or not having received any values communicated through the local self-identifier interfaces 433. The external tester can validate that the intended identifier value was registered, such as by using testmode/register readout functions.

Continuing with the illustrative example, the external tester and the stack 400 can repeat the above-described process iteratively, such that die 406c (core2) responds to a command 602b (cmd2) by incrementing to 0b0011 (individual die identifier 616b) from the value of 0b0010 received from the die 406b, and then die 406d (top core) responds to command 602c (cmd3) by incrementing to 0b0100 (individual die identifier 616c) from the value of 0b0011 received from the die 406c. The external tester can have a predetermined data regarding the stack height, which can be used to control the number of iterations for the self-identification sequence.

The external tester and the stack 400 can use the finalized and locally stored individual die identifiers 616 to access the individual dies within the stack 400. For example, the external tester can identify a targeted die for a command using the corresponding individual die identifier 616. For the stack 400, the external tester can provide the individual die identifier 616 associated with the command. The receiving die having the matching individual die identifier 616 (e.g., according to the access control circuit 436) can locally implement the die-level self-test or a commanded portion thereof. After the test, the targeted die can report the test results with the individual die identifier 616.

### Example Manufacturing and Operating Flows

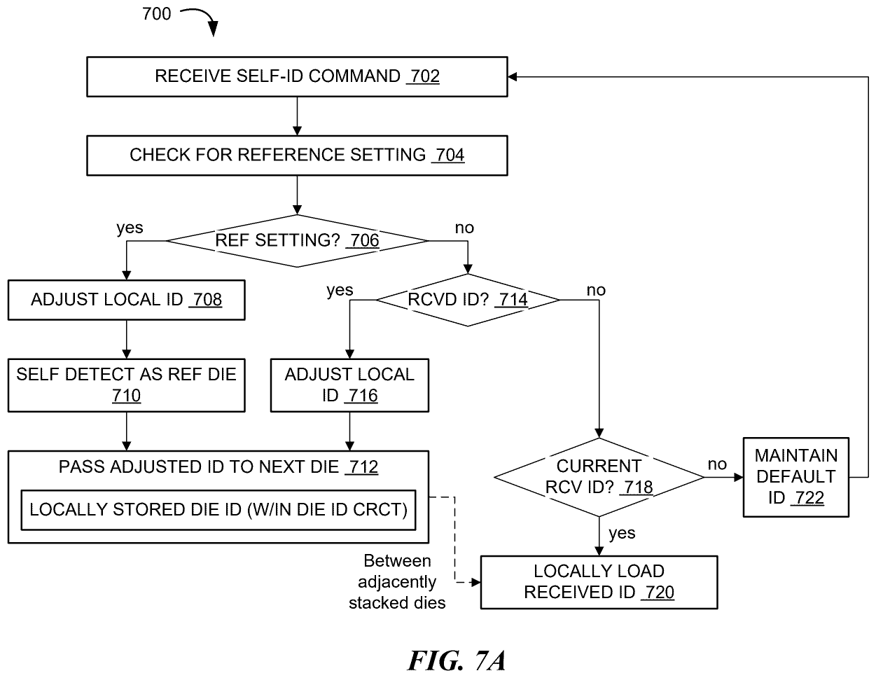

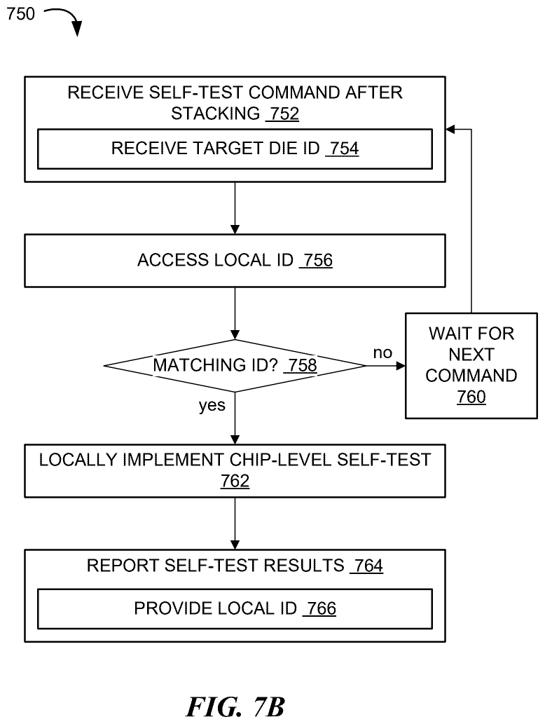

FIG. 7A and FIG. 7B are flow diagrams illustrating example methods of operating an apparatus in accordance with an embodiment of the present technology. FIG. 7A is a flow diagram illustrating an example method 700 for self-identifying dies within a die stack in accordance with an embodiment of the present technology. The method 700 can correspond to the self-identification process described above, such as in reference to FIG. 6A-FIG. 6B. The method 700 can be implemented by one or more or each of the dies within the die stack, such as the dies 406 of FIG. 4 within the die stack 400 of FIG. 4 and/or the dies 506 of FIG. 5 within the die stack 500 of FIG. 5. Stated differently, one or more or each of the dies within the stack can be configured to implement the method 700.

At block 702, the die(s) can receive a self-identification command. For example, each of the dies 406/506 can be configured to receive the self-identification command, such as the row/col command or the testmode input command, from an external tester through the local external interface (e.g., the interface 422 of FIG. 4 and/or the interface 522 of FIG. 5, such as test pads).

At block 704, the die(s) can check for reference setting. In other words, the die can determine whether it has a predetermined indication corresponding to being at a reference location (e.g., bottom or top) within the die stack. For example, the die can check whether the reference interface 438 is connected to a predetermined electrical potential, such as a predetermined voltage or an electrical ground, or a predetermined resistance value. Accordingly, the die can connect a corresponding measurement circuit to the referencing location.

At decision block 706, the die can determine whether the die has the reference setting. The die can determine the reference setting when the measurement circuit provides the predetermined referencing setting. At block 708, when the reference setting is detected, the die can adjust the local identifier value within the die identifier circuit 434 to the reference identifier value 614 of FIG. 6B from the default identifier value 612 of FIG. 6A. At block 710, the die can finalize the self-detection as the reference die, such as by changing an internal status indicator. Accordingly, the die can ignore subsequently received self-identification commands. At block 712, the die can pass the adjusted identifier (e.g., the reference identifier value 614) to the next die. In some embodiments, when the die is the last die (e.g., located at an end opposite the reference position), such as when the self-identifier vias are set to a predetermined termination setting (e.g., open circuit), the die can refrain from passing the adjusted identifier.

At decision block 714, when the reference setting is not detected, the die can determine whether an external die identifier (e.g., the identifier 620 of FIG. 6C) was previously received from the adjacently attached die following a prior command (e.g., in correspondence with block 712 implemented at the adjacently attached die). For example, the die can access the die identifier circuit 434 and determine that the external die identifier was received when the locally stored value differs from the default identifier value 612. If the die had previously received the identifier from the adjacent die, as illustrated at block 716, the die can adjust the locally stored identifier at the die identifier circuit 434. Accordingly, the die can finalize the adjusted identifier value in the die identifier circuit 434 as the individual die identifier 616. After finalizing, the die can pass the adjusted identifier to the next die, as illustrated at block 712 and described above. The die can finalize the identification process and ignore subsequent self-identification commands.

When the die identifier was not previously received from the adjacently attached die (e.g., the die identifier circuit 434 storing the default identifier value 612), at decision block 718, the die can determine whether the external die identifier has been received during the current iteration. If no external die identifier has been received, the die can maintain the default identifier value 612 as illustrated in block 722 and wait to receive the next self-identification command as shown by a feedback loop to block 702. If the external die identifier has been received from the adjacently stacked die (in correspondence to block 712), the die can locally load the external die identifier in the die identifier circuit 434 as illustrated in block 720. With the loaded external die identifier, the die can adjust the value in the die identifier circuit 434 in response to the next self-identifier command as described above for blocks 714 and 716.

FIG. 7B is a flow diagram illustrating an example method 750 for self-testing the dies within the die stack in accordance with an embodiment of the present technology. The method 750 can correspond to testing the individual dies after they are stacked together to form the die stack (e.g., stack 400 of FIG. 4 and/or the stack 500 of FIG. 5). The method 750 can be implemented by one or more or each of the dies within the die stack, such as the dies 406 of FIG. 4 within the die stack 400 and/or the dies 506 of FIG. 5 within the die stack 500. Stated differently, one or more or each of the dies within the stack can be configured to implement the method 750.

At block 752, the die can receive a self-test command after the stacking process. The die can receive the self-test command from the external test device through the external interface (e.g., interface 412/512) and the corresponding external communication bus (e.g., bus 420/520). At block 754, the die can receive an identifier of a targeted die along with the self-test command. In some embodiments, the die can receive the target die identifier through the external communication bus 420 of FIG. 4. In other embodiments, the die can receive the target die identifier through the die selector bus 540 of FIG. 5.

At block 756, the die can access the locally stored identifier value from the die identifier circuit 434/534. The die can compare the accessed local identifier value to the received targeted die identifier to determine whether the two values match, as shown in decision block 758. For example, the die can use the access control circuit 436 of FIG. 4/536 of FIG. 5 for the comparison. When the values don't match, the die can wait for the next command as illustrated in block 760 and a feedback loop to block 752.

When the compared values match, the die can determine that the received command is intended for itself and locally implement the chip-level self-test or a portion thereof, as shown in block 762. For example, the die can use the access control circuit 436/536 to control the die communication circuit 414/514 and allow the received command to be processed by the die-level test circuit 416 of FIG. 4/516 of FIG. 5.

At block 764, the die can report the result/response after locally implementing the chip-level self-test or the commanded portion thereof. The die can communicate the result/response through the external communication bus 420/520 to the external tester. At block 766, the die may report the local identifier value from the die identifier circuit 434/534 along with the results/response to the external tester. In some embodiments, the die can report the local identifier value through the external communication bus 420/520. In other embodiments, the die can report the local identifier value through the die selector bus 540.

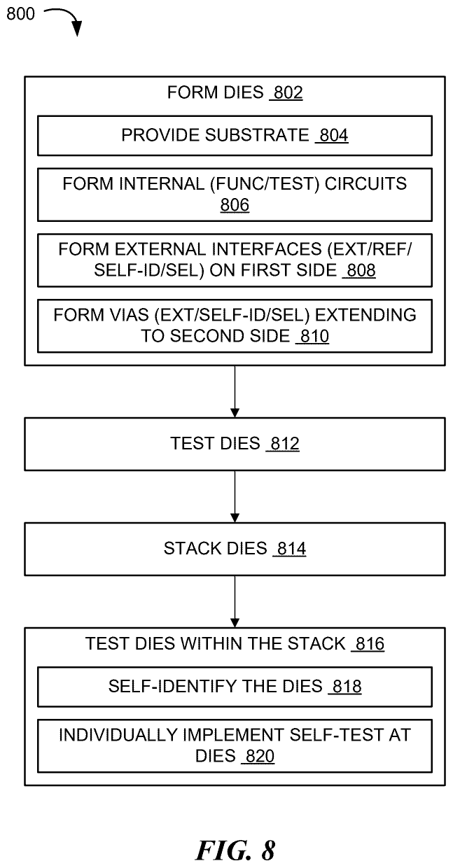

FIG. 8 is a flow diagram illustrating an example method 800 of manufacturing an apparatus in accordance with an embodiment of the present technology. The method 800 can be for manufacturing the die stack 400 of FIG. 4, the die stack 500 of FIG. 5, or both.

At block 802, the method 800 can include forming the individual dies (e.g., the dies 106 of FIG. 1, the dies 406 of FIG. 4, and/or the dies 506 of FIG. 5). Forming the dies can include providing a substrate, such as a silicon substrate/wafer, as shown in block 804. At block 806, the provided substrate can be processed to form internal circuits. For example, the die external interface, the functional circuits, the die-level test circuits, the die identifier circuit, the access control circuit, and/or the like described above. The circuits can be formed based on adding dopants, connecting doped regions, and/or the like.

Further, as shown at block 806, the provided substrate can be processed to form external interfaces (e.g., pads and related connections). For example, various layers (e.g., oxide layers, metal layers, masks, solder resist, etc.) can be formed and/or removed to finalize an external surface and the communication pads thereon. The formed interfaces can include the die external interface, the self-identifier interface, the die selector interface, the reference interface, or a combination thereof.

At block 810, the provided substrate can be processed to form vias extending to and exposed on a side opposite the external interfaces. For example, the opposing surface of the substrate can be masked with an opening over the targeted locations of the vias. The substrate material can be etched away using chemical etchants, light, and/or the like to form a depression. The depression can be filled with conductive material through metallic deposition processes to form the TSVs. The formed vias can include the external interface vias, the self-identifier vias, the die selector vias, or a combination thereof. In some embodiments, forming the dies can include singulating the dies from a corresponding wafer/substrate.

At block 812, the method 800 can include testing the dies (e.g., singulated dies or dies formed on wafers). For example, the formed dies can be coupled to the external tester. The external tester and the dies can interact with each other to operate the die-level test circuit within the dies. Accordingly, the dies can test and validate the functional circuits within the die. For memory dies, the self-test can include writing a predetermined pattern of data, reading the written data, and comparing the read data to the predetermined pattern.

At block 814, the method 800 can include stacking the validated dies to form die stacks, such as the die stack 400, the die stack 500, or the like. The dies can be stacked by being attached, such as through direct bonding, solder reflow, or the like, over one another. In some embodiments, the stacks can be formed based on boding the wafers together and then singulating the stacked wafers to form the individual stacks.

At block 816, the method 800 can include testing the dies within the formed stack. The test can include connecting the stack to the external tester, such as using the external interface, the self-identifier interface, the die selector interface, and/or the like on a reference die (e.g., a bottom die within the stack). Also, the test can include establishing the reference setting on the reference die, such as by grounding the reference interface.

Based on the connections, the dies within the stack can be individually tested using one or more circuits/components and processes described above. For example, at block 818, the external tester and the dies within the stack can interact with each other according to the method 700 of FIG. 7A to self-identify the individual dies within the stack. Also, at block 820, the external tester and the dies within the stack can interact with each other according to the method 750 of FIG. 7B to self-test one or more or each of the dies within the stack.

The stack testing mechanism, including the external communication bus, the self-identifier bus, the die selector bus, the die identifier circuit, access control circuit, and the self-identifying feature, can provide individualized access to each die within the die stack. The stack testing mechanism can be leveraged to utilize the existing die-level test circuits within each of the dies, even after stacking the dies and/or before mounting the stack onto a further interface (e.g., the interposer 112 of FIG. 1). As a result, the stack testing mechanism can detect potential manufacturing errors/failures that may have occurred during the die stacking process, thereby providing opportunities to remedy and recover from the errors/failures. Accordingly, the stack testing mechanism can further improve the overall manufacturing yield and efficiency.

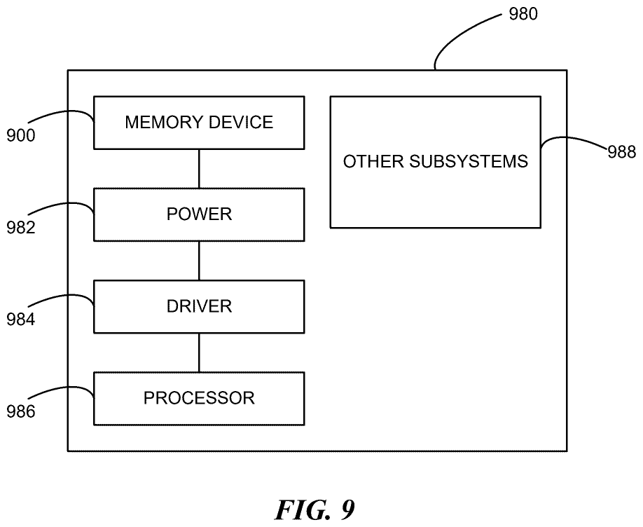

FIG. 9 is a block diagram of a system that includes an apparatus in accordance with embodiments of the present technology. Any one of the foregoing apparatuses (e.g., memory devices) described above with reference to FIGS. 1, 2, 4-8 can be incorporated into or implemented in memory (e.g., a memory device 900) or any of a myriad of larger and/or more complex systems, a representative example of which is system 980 shown schematically in FIG. 9. The system 980 can include the memory device 900, a power source 982, a driver 984, a processor 986, and/or other subsystems or components 988. The memory device 900 can include features generally similar to those of the apparatus described above with reference to FIGS. 1, 2, 4-8 and can therefore include various features for performing a direct read request from a host device. The resulting system 980 can perform any of a wide variety of functions, such as memory storage, data processing, and/or other suitable functions. Accordingly, representative systems 980 can include, without limitation, hand-held devices (e.g., mobile phones, tablets, digital readers, and digital audio players), computers, vehicles, appliances and other products. Components of the system 980 may be housed in a single unit or distributed over multiple, interconnected units (e.g., through a communications network). The components of the system 980 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of HBM and DRAM devices. Apparatuses configured in accordance with other embodiments of the present technology, however, can include other types of suitable storage media in addition to or in lieu of HBM and/or DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1, 2, 4-9.

What is claimed is:

1. A stack of memory dies, comprising:
a first die; and
a second die stacked over the first die, wherein each of the first and second dies include:
a functional circuit configured to perform memory operations;
a die-level test circuit coupled to the functional circuit and configured to self-test the functional circuit;
a test pad on a first side of a corresponding die, the test pad coupled to the die-level test circuit and configured to provide a communicative connection to an external tester and receive an incoming self-test command;
an external communication via extending to and exposed at a second side of the corresponding die, the external communication via coupled to the test pad and configured to provide the communicative connection across a thickness of the corresponding die;
a die identifier circuit coupled to the die-level test circuit and configured to determine and store an identifier value unique to the corresponding die; and
an access control circuit coupled to the die identifier circuit and configured to enable processing of the incoming command when a corresponding target die identifier matches the locally stored identifier value.

2. The stack of memory dies of claim 1, wherein each of the first and second dies includes:
a self-identifier pad on one of the first side or the second side of the corresponding die, the self-identifier pad coupled to the die identifier circuit and configured to receive an external die identifier from an external circuit connected on the one of the first side or the second side; and
a self-identifier via on other of the first side or the second side of the corresponding die, the self-identifier via coupled to the die identifier circuit and configured to communicate the locally stored identifier value of the corresponding die to a further external circuit connected on the other of the first side or the second side,
wherein the die identifier circuit is configured to:
determine the locally stored identifier value based on the external die identifier, and
send the locally stored identifier value through the self-identifier via.

3. The stack of memory dies of claim 1, wherein each of the first and second dies includes:
a die selector pad on one of the first side or the second side of the corresponding die, the die selector pad coupled to the die identifier circuit and configured to receive the incoming target die identifier from the external tester; and
a die selector via on other of the first side or the second side of the corresponding die, the die selector via coupled to the die identifier circuit and configured to send the incoming target die identifier to a stacked die.

4. The stack of memory dies of claim 1, wherein the test pad of the second die is connected to the external communication via of the first die, the test pad and the external communication via of the first and second dies comprising an external communication bus configured to broadcast the incoming self-test command to the first and second dies.

5. The stack of memory dies of claim 1, wherein each of the first and second dies includes a reference interface configured to identify that the corresponding die is at a reference position within the die, wherein the reference position corresponds to a bottom die or a top die.

6. An apparatus, the apparatus comprising:
a die-level test circuit configured to self-test a function of the apparatus, wherein the apparatus is configured to be stacked with one or more devices to form a device stack;
an external interface coupled to the die-level test circuit and configured to provide a communicative connection to an external tester;
an external communication via coupled to and extending away from the external interface across a thickness of the apparatus, the external communication via configured to continue the communicative connection to a stacked device;
an identifier circuit coupled to the die-level test circuit and configured to locally store an identifier unique to the apparatus for identifying the apparatus within the device stack and self-testing the apparatus; and
an access control circuit coupled to the identifier circuit and configured to selectively control the die-level test circuit during the self-test for the stack based on identifying incoming communication matching the locally stored identifier, wherein from the incoming communication is from the external tester.

7. The apparatus of claim 6, further comprising:
a self-identifier interface coupled to the identifier circuit and configured to receive an external identifier from the external tester or another device within the die stack; and
a self-identifier via coupled to and extending away from the self-identifier interface across the thickness of the apparatus,
wherein the identifier circuit is a counter configured to determine the locally stored identifier value based on incrementing from the external identifier.

8. The apparatus of claim 6, further comprising:
a reference interface configured to identify that the apparatus is positioned at a reference position within the die,
wherein the identifier circuit is configured to:
detect an indication for the reference position through the reference interface; and
determine the locally stored identifier value to a reference identifier value in response to detecting the indication for the reference position.

9. The apparatus of claim 8, wherein:
the indication corresponds to a connection to an electrical ground; and
the reference position corresponds to a bottom position within the device stack.

10. The apparatus of claim 6, further comprising:
a die selector interface coupled to the identifier circuit and configured to receive the incoming communication including a target die identifier from the external tester for implementing a self-test of the apparatus; and
a die selector via coupled to and extending away from the die selector interface across the thickness of the apparatus, the die selector via configured to communicate the target die identifier to the one or more devices within the device stack.

11. The apparatus of claim 6, wherein the incoming communication includes a command and a target die identifier and is received through the external interface.

12. The apparatus of claim 6, wherein the apparatus comprises a semiconductor die.

13. The apparatus of claim 12, wherein:
the semiconductor die comprises a memory device and the function includes storing and providing access to data; and
the external interface includes a test pad.

14. A method of operating a die having a local test circuit and configured to provide a function, the method comprising:
receiving a self-identifying command at the apparatus from an external tester, wherein the self-identifying command is provided to a stack that includes the die stacked with at least a further die;
determining an individual die identifier in response to the self-identifying command, wherein the individual die identifier uniquely identifies the die within the stack;
receiving a self-test command from the external tester, wherein the self-test command is configured to test one die within the stack;
receiving a target identifier corresponding to the self-test command, wherein the target identifier represents the one die targeted for the self-test command;
determining that the received target identifier matches the individual die identifier; and
implementing a self-test of the function using the local test circuit in response to determining the match.

15. The method of claim 14, wherein determining the individual die identifier includes:
receiving a further identifier from the further die; and
determining the individual die identifier for the die based on adjusting the further identifier.

16. The method of claim 14, further comprising:
communicating the individual die identifier to the further die.

17. A method of manufacturing an apparatus, the method comprising:
providing a first substrate having a first test pad on a first bottom surface and a first external interface via connect to the first test pad and extending toward a first top surface, the first substrate including a first test circuit configured to self-test a first functional circuit within the first substrate based on communications through the first test pad;
providing a second substrate having a second test pad on a second bottom surface, the second substrate including a second test circuit configured to self-test a second functional circuit within the second substrate based on communications through the second test pad; and
stacking the second substrate over the first substrate, wherein stacking includes coupling the second test pad to the first external communication via.

18. The method of claim 17, wherein:
the provided first substrate includes:
a first self-identifier interface on the first bottom surface,
a first self-identifier via connect to the first self-identifier interface and extending toward the first top surface, and
a first identifier circuit coupled to the first self-identifier interface and the first self-identifier via, the first die identifier circuit configured to determine and store a first identifier;
the provided second substrate includes:
a second self-identifier interface on the second bottom surface,
a second identifier circuit coupled to the second self-identifier interface and configured to determine and store a second identifier; and
stacking includes coupling the second self-identifier interface to the first self-identifier via, wherein the first and second identifier circuits are configured to determine the respective first and second identifiers based on communicating with each other through the coupled second self-identifier interface and the first self-identifier via.

19. The method of claim 18, further comprising:
testing the first functional circuit using the first test circuit within the first substrate based on:
receiving a first test command accompanied with a first target identifier from an external tester;
determining, at the first substrate, that the first target identifier matches the first identifier locally stored on the first substrate;
implementing the first test command with the first test circuit; and
testing the second functional circuit using the second test circuit within the second substrate based on:
receiving the first test command accompanied with the first target identifier;
determining, at the second substrate, that the first target identifier is different from the second identifier locally stored on the second substrate;
ignoring the first test command.

20. The method of claim 19, wherein:
providing the first substrate includes forming the first test pad, the first external interface via, the first test circuit, and the first functional circuit on a first wafer;
providing the second substrate forming the second test pad, the second test circuit, and the second functional circuit on a second wafer;
stacking the second substrate over the first substrate includes wafer bonding the first wafer and the second wafer, wherein the first and second functional circuits are tested after wafer bonding;
the method further comprising:
singulating a stack that includes the first substrate stacked with the second substrate from stacked first and second wafers.
